(19) United States
(12) Patent Application Publication
(10) Pub. No.: US 2013/0040054 A1
(43) Pub. Date: Feb. 14, 2013

(54) COATING DEVICE AND METHOD FOR OPERATING A COATING DEVICE HAVING A SHIELDING PLATE

(71) Applicants: Gerhard Karl Strauch, Aachen (DE); Walter Franken, Eschweiler (DE); Marcel Kollberg, Wurselen (DE); Florenz Kittel, Aachen (DE); Markus Gersdorff, Herzogenrath (DE); Johannes Käppeler, Wurselen (DE)

(72) Inventors: Gerhard Karl Strauch, Aachen (DE); Walter Franken, Eschweiler (DE); Marcel Kollberg, Wurselen (DE); Florenz Kittel, Aachen (DE); Markus Gersdorff, Herzogenrath (DE); Johannes Käppeler, Wurselen (DE)

(73) Assignee: AIXTRON SE, Herzogenrath (DE)

(21) Appl. No.: 13/576,942

(22) PCT Filed: Feb. 8, 2011
(86) PCT No.: PCT/EP2011/051793

§ 371 Date: Oct. 24, 2012

(30) Foreign Application Priority Data
Feb. 17, 2010 (DE) 10 2010 000 447.2

(51) Int. Cl. C23C 16/04; C23C 16/458; C23C 16/455

(52) U.S. Cl. 427/248.1; 118/720

(57) ABSTRACT

A device for treating a substrate (12) includes a conveying device (13) for loading and unloading substrates or masks (10, 10′, 10″, 10″′) into and from a process chamber (1) through loading openings (6, 7). A shielding plate (11), used to shield the substrate (12) or the mask (10) from the influence of heat is moved between a shielding position and a storage position during the substrate treatment and, after the substrate (12) is treated, from the storage position back into the shielding position. In the storage position, the shielding plate (11) is situated inside a storage chamber (2, 3).

The invention relates to a device for coating a substrate, having a process chamber in which a temperature-controllable gas inlet element for introducing a starting material together with a carrier gas, and a susceptor for receiving the substrate are situated, having a substrate storage chamber, for storing a substrate, which is connected to the process chamber via a loading opening, and having a conveying device for loading and unloading substrates to and from the process chamber.

The invention further relates to a method for operating this type of device.

DE 101 59 702 A1 describes a device comprising a process chamber having a gas inlet element and a susceptor, the process chamber being loadable with substrates using a gripper arm which removes the substrates from a substrate storage chamber. A coating process takes place within the process chamber. For this purpose, gaseous starting materials are introduced, with the aid of a carrier gas, by the gas inlet element into the process chamber. A thin layer is deposited on the substrate surface.

A chemical or a physical coating process may be involved. DE 10 2008 026 974 A1 describes, for example, a device having an evaporator for evaporating a solid or liquid starting material. The evaporated starting material together with a carrier gas is introduced via a carrier gas line into a pyrolysis chamber. The starting material may be polymeric paraxylylenes. The evaporated dimer is decomposed into a monomer in the pyrolysis chamber. The monomer together with the carrier gas is introduced into the gas inlet element. The gas inlet element is located in a process chamber which is sealed against the outside in a gas-tight manner, and has a gas discharge surface with a multiplicity of openings arranged in a screen-like manner, through which the carrier gas transporting the starting material flows into the process chamber. The gas inlet element is temperature-controlled by heating. A cooled susceptor is located beneath the gas inlet element. A substrate, for example a glass plate, may be placed on the cooled substrate bearing surface of the susceptor. The substrate is coated with a polymer layer, polymer which is introduced in gaseous form into the process chamber being condensed therein.

DE 10 2008 037 387 describes a mask arrangement. The shadow mask described therein is placed on the surface of a substrate to be coated in order to coat the substrate in a structured manner.

DE 102 32 731 A1 describes a coating device by means of which semiconductor layers composed of elements of groups IV, III-IV, and II-VI of the periodic table as well as organic materials may be deposited.

It is an object of the invention to design a more efficient device of the generic kind.

The object is achieved by the invention set forth in the claims, each claim representing an independent achievement of the object, and being combinable with any other claim.

The device according to the invention is particularly suited for depositing paraxylylenes or also multicomponent layers, for example OLEDs as well as semiconductor layers. The starting materials are prepared in a gas mixing system or a gas preparation device located outside the process chamber, and pass into the heated gas inlet element through a feed line which in particular is temperature-controlled. The gas inlet element has a hollow body with at least one chamber into which the carrier gas transporting the starting material is introduced. The gas inlet element has a gas discharge surface which has a circular, but preferably rectangular, in particular square, outline in plan view. The plan view outline substantially corresponds to the surface area of the substrate. The gas discharge surface contains a multiplicity of gas discharge openings, arranged in a screen-like manner, through which the process gas flows into the process chamber, the base of which is formed by a susceptor. This gas inlet element, having the shape of a shower head, is heated to temperatures of 200° C. to 400° C. The process chamber is operated in a pressure range between 0.1 mbar and 2 mbar, using a vacuum device. The susceptor is a cooled body having a substrate bearing surface. The bearing surface is selected in such a way that heat may be dissipated from the substrate toward the susceptor. The susceptor is temperature-controlled to temperatures between −30° C. and 80° C. The coating process takes place with the substrate actively cooled, so that the starting materials may be deposited on the substrate at the low temperatures. In the method according to the invention, it is provided that the loading and unloading of the process chamber take place with the gas inlet element heated. To avoid the substrate heating up before it is placed on the susceptor, a shielding plate is introduced between the gas inlet element and the susceptor before the loading or unloading takes place. Alternatively, the shielding plate may be used to protect a mask, which is placed on the substrate for structuring the layer to be deposited, from heating up. The shielding plate is located directly beneath the gas discharge surface of the gas inlet element. The shielding plate has a highly reflective surface, so that the substrate or the mask is protected against radiation from the gas inlet element. The shielding plate may have a highly reflective coating on both sides. The shielding plate is preferably composed of two glass or quartz plates extending parallel, between which a thin metal foil is situated. This may be a foil 100 μm thick which is made of Invar, gold, or aluminum. The foil is floatingly-mounted between the glass plate and the quartz glass plate. The foil has an emissivity ε<0.1. To protect the shielding plate outside the process chamber during the coating process, an additional storage chamber is provided in which the shielding plate is accommodated. This storage chamber may be a mask storage chamber in which at least one mask, which is applied to the substrate surface for the structured coating of the substrate surface, is stored. In a preferred embodiment of the invention, the shielding plate is the transport element for bringing the mask from the mask storage chamber into the process chamber. For this purpose, the shielding plate has holding means. The holding means may be situated on the underside of the shielding plate and engage in a positive-fit manner with corresponding counter-holding means of the mask. The mask may be removed from a mask magazine in the mask storage chamber with the aid of the shielding plate. By means of the shielding plate, the mask is shielded from the heated gas inlet element during the mask transfer. The mask is thus protected against a temperature increase. Thus, the shielding plate may be used to protect not only the substrate, but also the mask, against a temperature increase. The mask magazine may be vertically displaced within the storage chamber, similarly as for an elevator. Masks of various designs may be stored in the magazine in vertically superposed pockets. This magazine also has a compartment into which the shielding plate is able to enter. The shielding plate is preferably able to enter into each of the magazine compartments of the magazine in which a mask is also accommodated. A shielding plate displacement device may be situated within the magazine storage chamber. The shielding plate displacement device may be a rail system. The rail system may have two pairs of rails, one rail pair being situated in the magazine and a second rail pair being situated in the process chamber. The shielding plate may have a roller guide by means of which the shielding plate is guided on the pair of rails. The horizontal displacement drive for displacing the shielding plate between its shielding position beneath the gas inlet element and its storage position inside the magazine may be a pneumatic drive or an electric linear drive. This may also be a spindle drive. The substrate storage chamber may likewise have a magazine, in which various substrates are situated in vertically superposed pockets. The substrates may rest on in particular fork-shaped substrate holders which are also used for bringing the substrate into the process chamber. Each storage chamber is connected to the process chamber via loading/unloading openings which are closable in a gas-tight manner. The loading openings may be closed using gas-tight gates. The mask storage chamber as well as the substrate storage chamber may be evacuated using a vacuum device. The substrate storage chamber may be brought to atmospheric pressure in order to remove the substrates from the overall device. The susceptor may be water-cooled. The susceptor may be displaceable in the vertical direction. In the loading/unloading position, the susceptor has a lowered position. In this position, support pins protrude from the substrate bearing surface of the susceptor.

A substrate may be placed on these support pins by means of a conveying device, for example the fork-shaped substrate holder. This is achieved through the loading opening. The shielding plate has previously been brought beneath the heated gas inlet element by the above-described displacement of the shielding plate. The susceptor is raised to bring it into surface contact with the underside of the substrate. However, the substrate may also be set down on a stationary susceptor with the aid of retractable support pins.

In the method according to the invention, the loading and unloading of one or more substrates into and from the process chamber is carried out with the gas inlet element heated and the susceptor cooled. During the loading/unloading phase, only a carrier gas passes through the gas inlet element and into the process chamber. At the beginning, the unloaded susceptor is at a maximum distance from the gas inlet element. The loading gate for the magazine storage chamber is opened. With the aid of the shielding plate displacement device, the shielding plate is moved into the process chamber and positioned beneath the gas inlet element in such a way that the shielding plate reflects the heat radiation emanating from the gas inlet element. The shielding plate has an insulating effect, and is used to interrupt, but at least inhibit, the inflow of heat from the gas inlet element to the substrate. The magazine is then brought into a vertical position in which a mask to be used is situated directly in front of the loading opening. With the aid of the shielding plate displacement device, the shielding plate is moved back into the magazine and directly above the mask to be used, or the mask frame holding the mask. The mask frame or the mask is secured to the underside of the shielding plate, using a holding device, and is brought into the process chamber by the shielding plate. The loading opening to the substrate storage chamber is then opened, and a substrate is brought onto the above-mentioned pins by means of a conveying device. The substrate is now located between the susceptor and the shielding plate. As a result of the reflective or insulating effect of the shielding plate, there is no harmful heating of the substrate arising out of the heat emitted by the gas inlet element. The substrate is placed on the substrate set-down surface of the susceptor by lowering the pins or raising the susceptor, so that the substrate is cooled by the susceptor. The mask is then placed on the substrate, either by an upward movement of the susceptor or by a downward movement of the shielding plate. The shielding plate is subsequently moved back into the magazine in the mask storage chamber. After the gates of the loading openings have been closed gas-tight, the process gas is introduced into the process chamber so that a layer may be deposited on the substrate. Before the substrate is placed on the susceptor, the susceptor together with the substrate and the mask may also be jointly lowered. The mask is not in contact with the susceptor when the susceptor is lowered.

The above-mentioned organic or inorganic compounds may be used as starting material. Preferably paraxylylenes are deposited on a substrate, using the device. However, OLED layers may be deposited. In principle, the device is also suitable for MOCVD.

An exemplary embodiment of the invention is explained below with reference to accompanying drawings, which show the following:

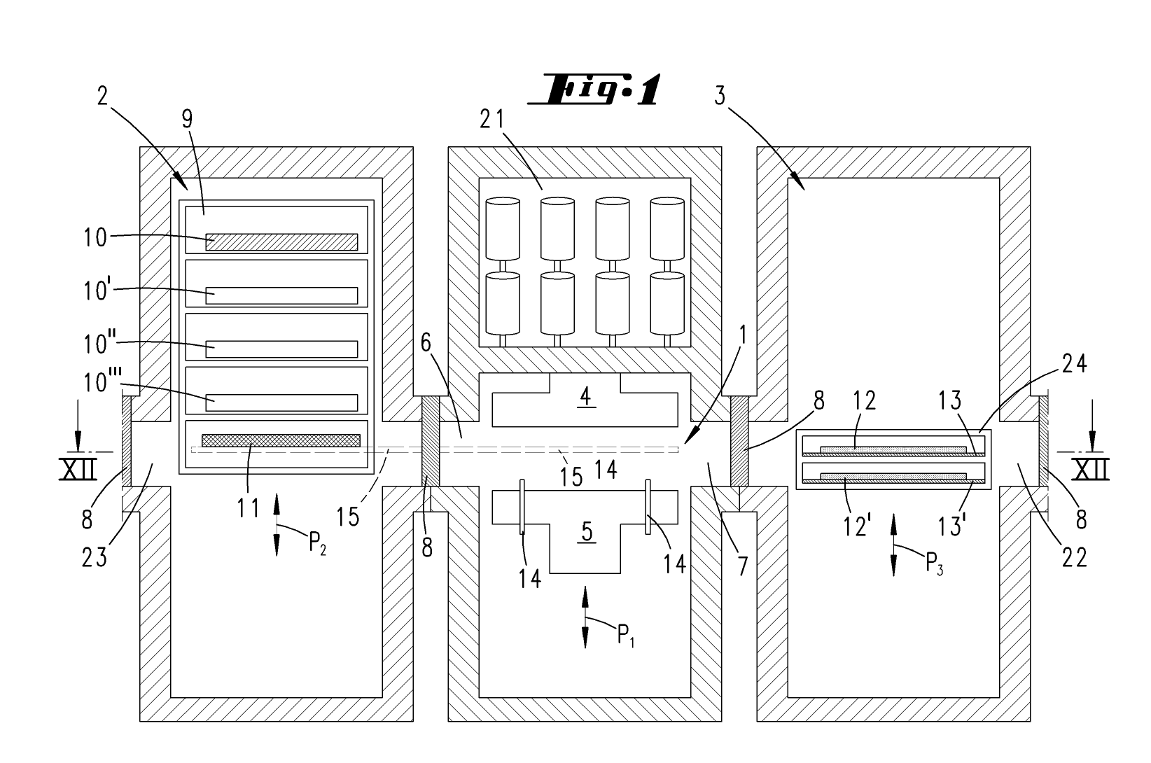

FIG. 1 schematically shows, in the form of a vertical section, the essential elements of a device composed of a process chamber 1, a mask storage chamber 2, and a substrate storage chamber 3, in a starting position with the loading gates 8 closed and the process chamber 1 empty;

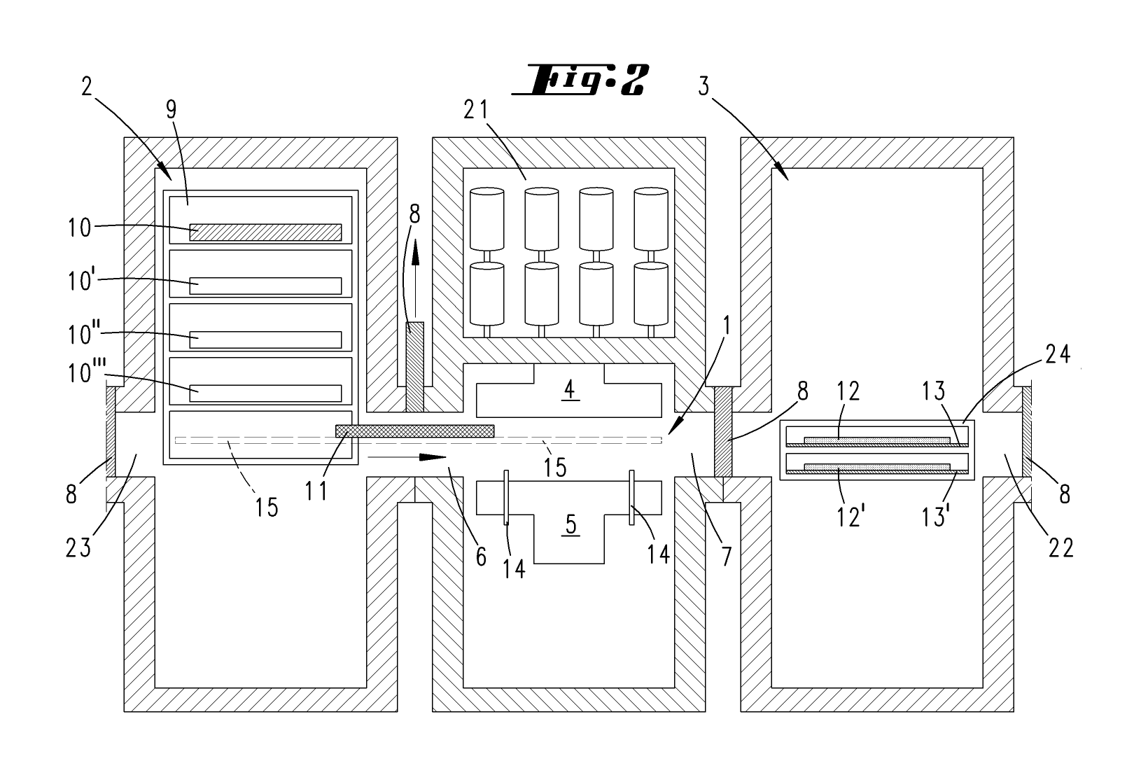

FIG. 2 shows an illustration corresponding to FIG. 1, in which a shielding plate 11 is transported from a magazine 9 in the mask storage chamber 2, through a loading opening 6 and into the process chamber 1;

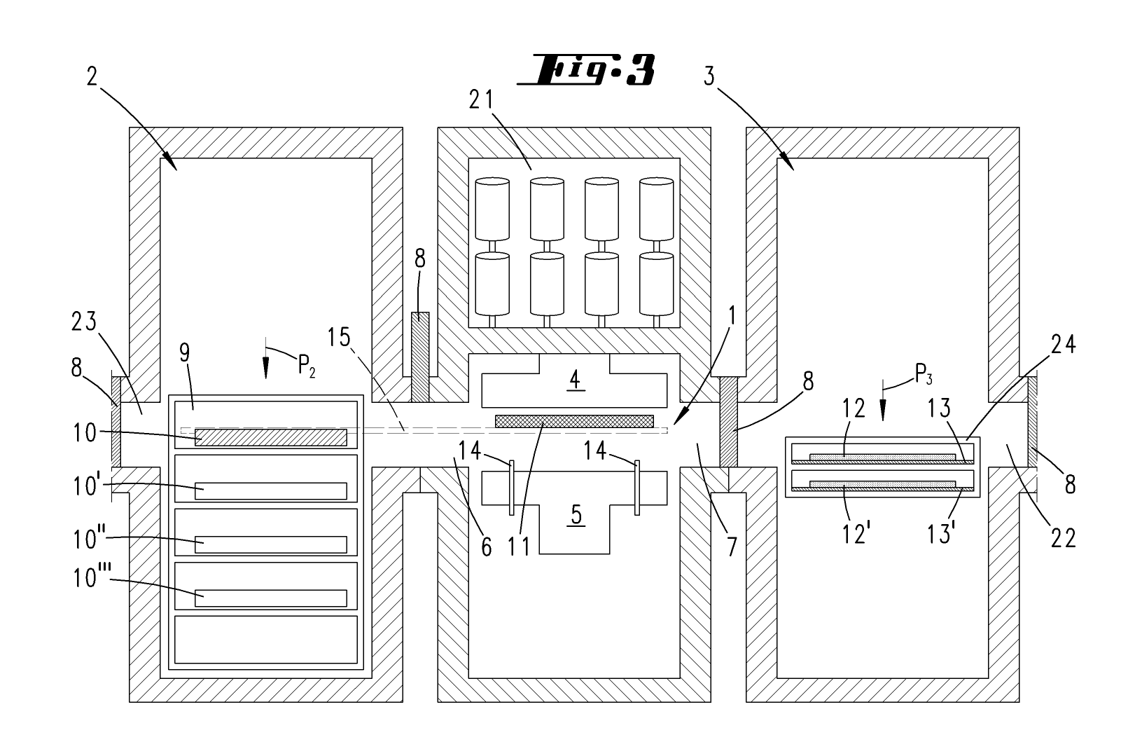

FIG. 3 shows an illustration subsequent to FIG. 2, in which the shielding plate 11 is located beneath a gas inlet element 4, and the magazine 9 has been lowered in the direction of the arrow P₂, so that a mask 10 is situated in front of the loading opening 6;

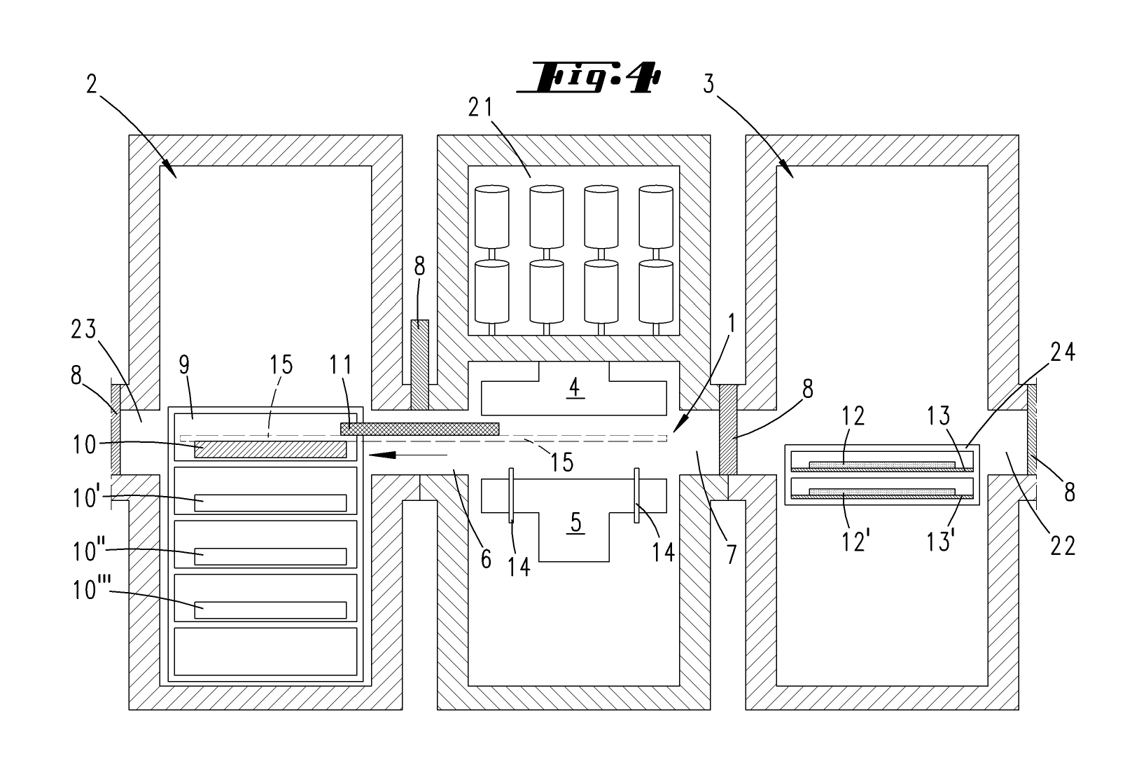

FIG. 4 shows an illustration subsequent to FIG. 3, in which the shielding plate 11 is brought through the loading opening 6 in the direction above the mask 10 situated in front of the loading opening 6;

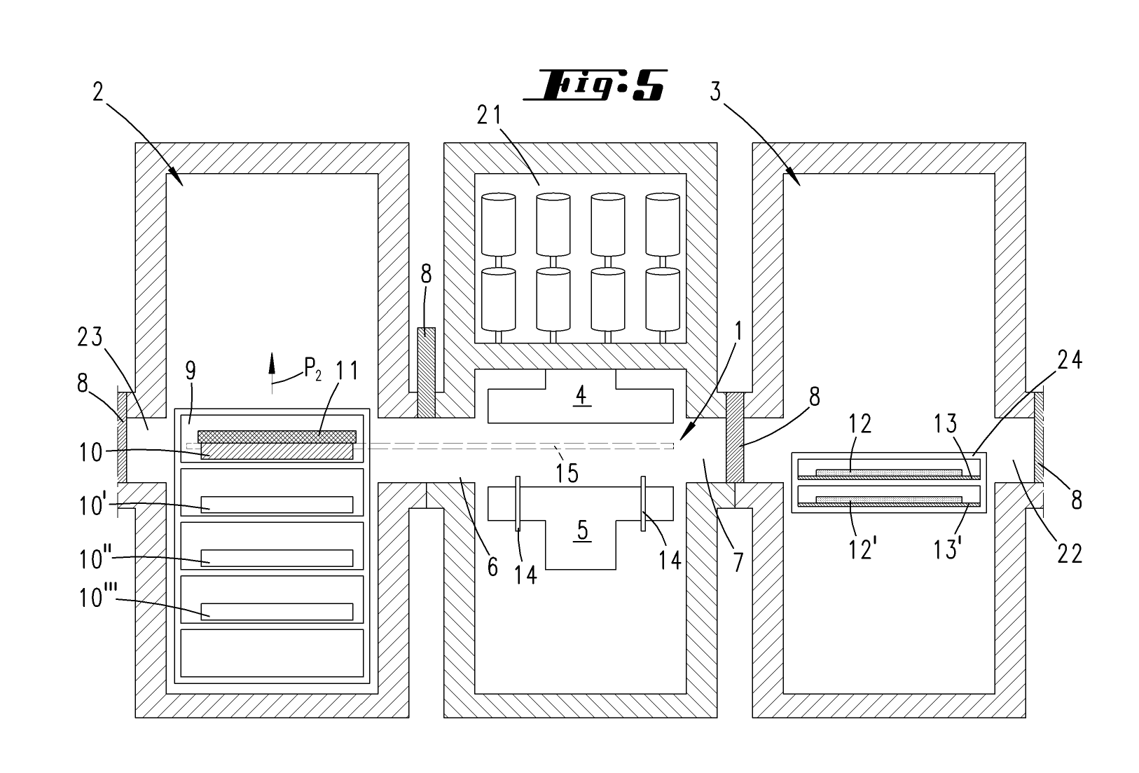

FIG. 5 shows an illustration subsequent to FIG. 4, in which the mask 10 is secured beneath the shielding plate 11 by means of mountings;

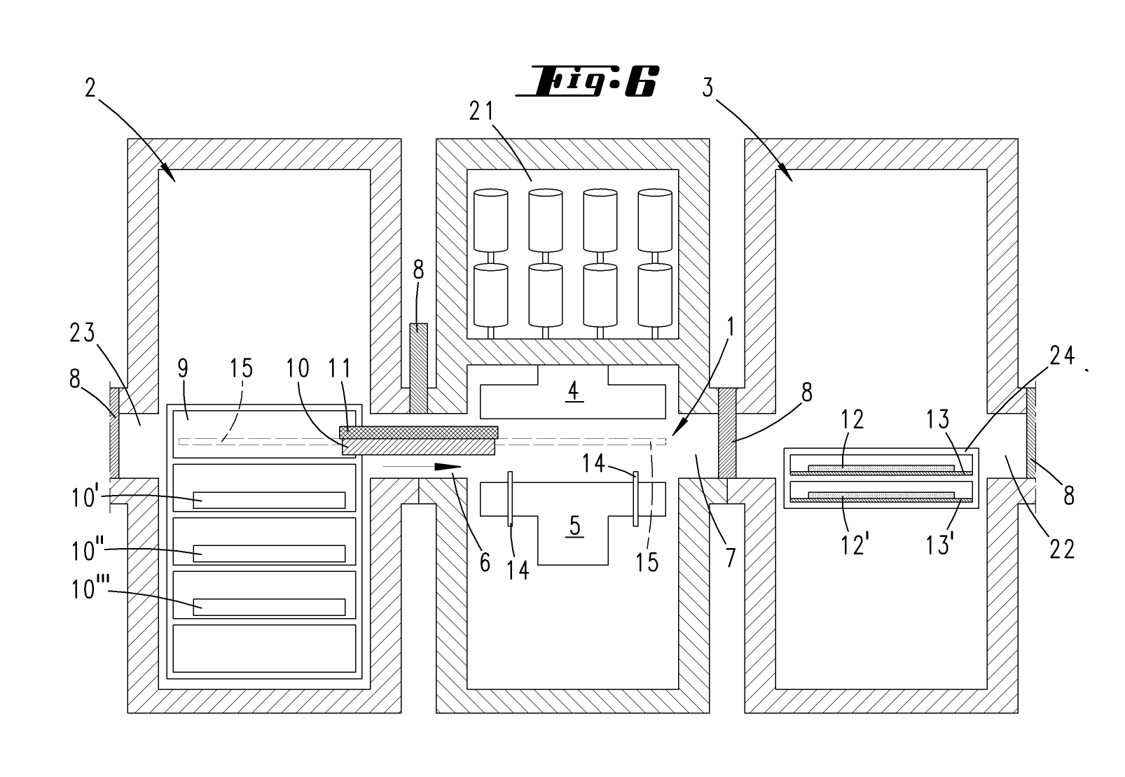

FIG. 6 shows an illustration subsequent to FIG. 5, in which the mask 10 together with the shielding plate 11 is transported through the loading opening 6 and into the process chamber 1;

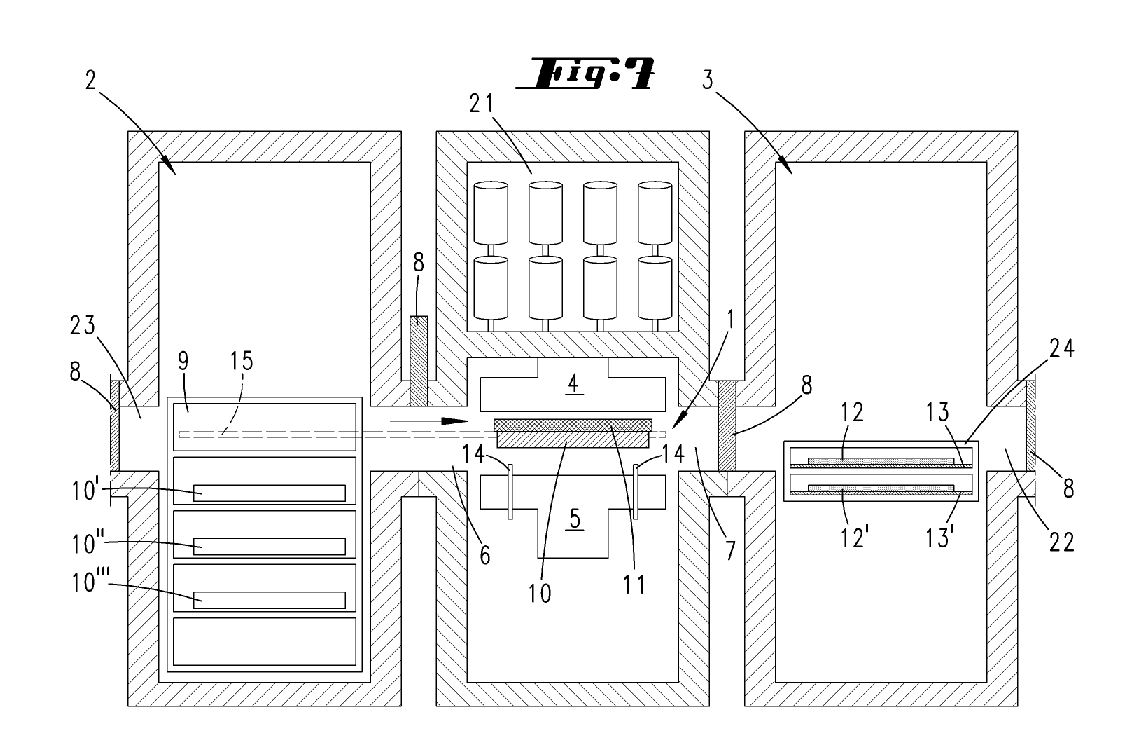

FIG. 7 shows an illustration subsequent to FIG. 6, in which the shielding plate 11 together with the mask 10 which it carries is positioned beneath the gas inlet element 4;

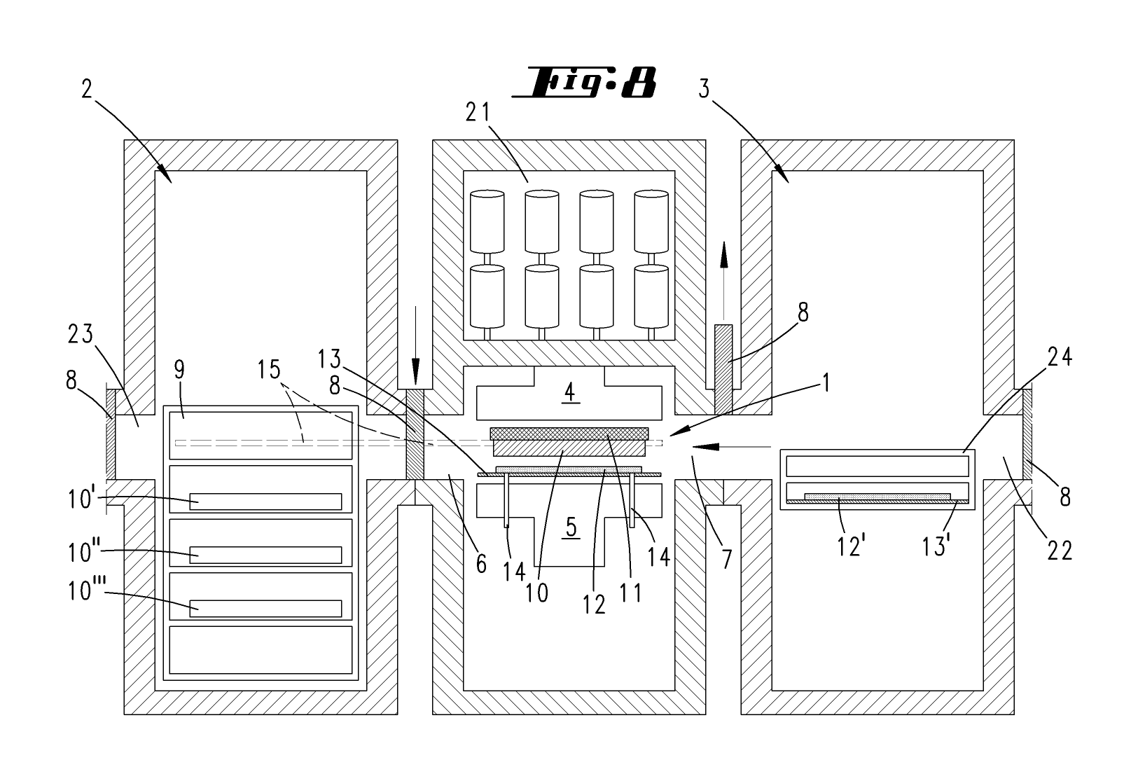

FIG. 8 shows an illustration subsequent to FIG. 7, in which the gate of the loading opening 6 is closed, the gate 8 of the loading opening 7 is open, and a substrate 12 to be coated has been brought into the process chamber 1, in a position above a susceptor 5 and beneath the mask 10, by means of a substrate holder 13;

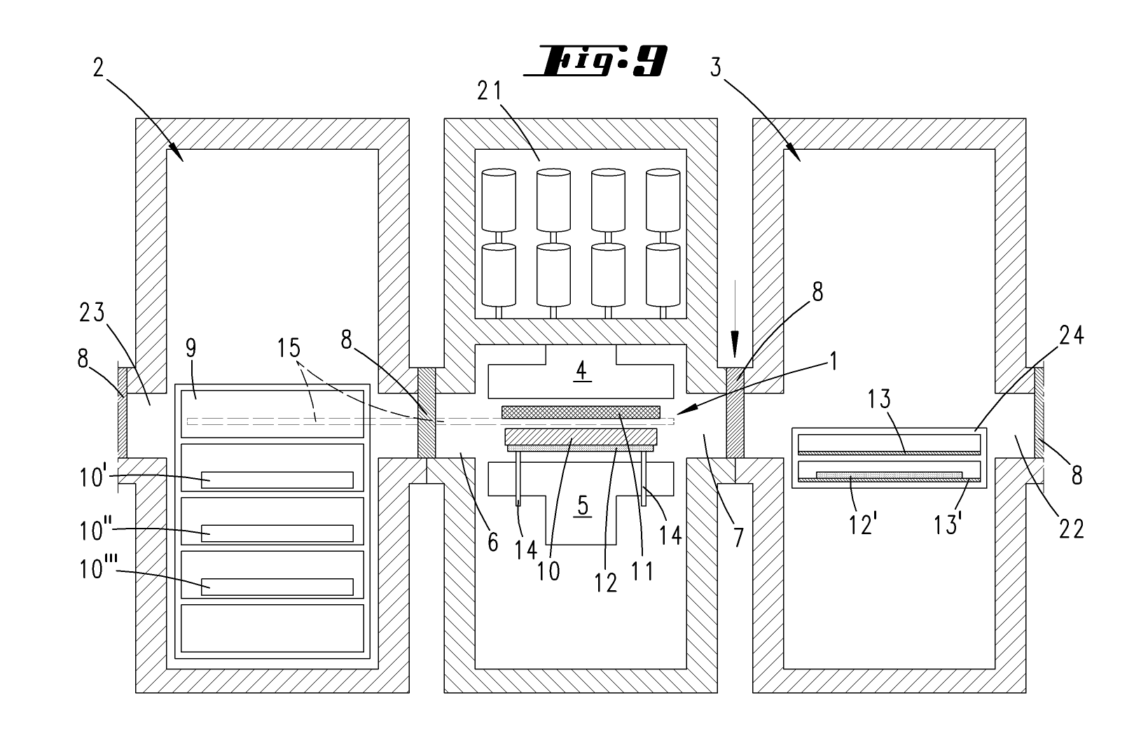

FIG. 9 shows an illustration subsequent to FIG. 8, in which the mask 10 has been lowered onto the substrate 12 which rests on support pins 14, and the substrate holder 13 has been retracted from the process chamber 1 and into the substrate storage chamber 3;

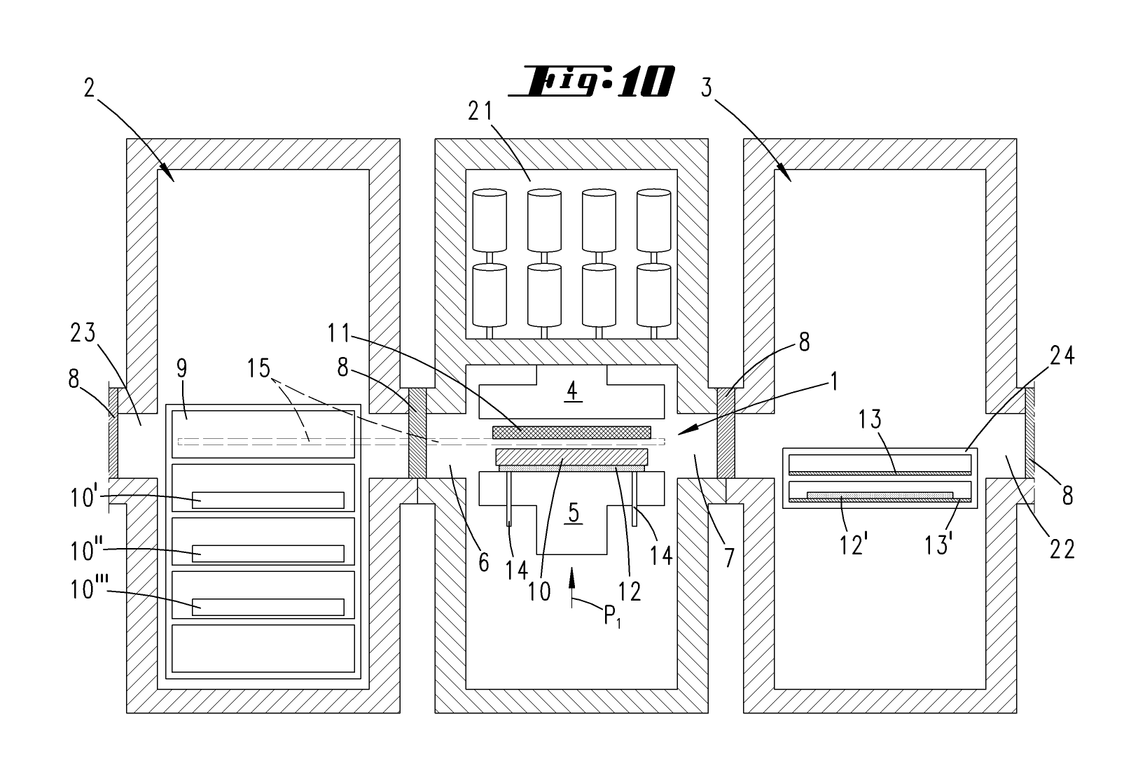

FIG. 10 shows an illustration subsequent to FIG. 9, in which the substrate rests on the top side of the susceptor 5 after the susceptor has been raised;

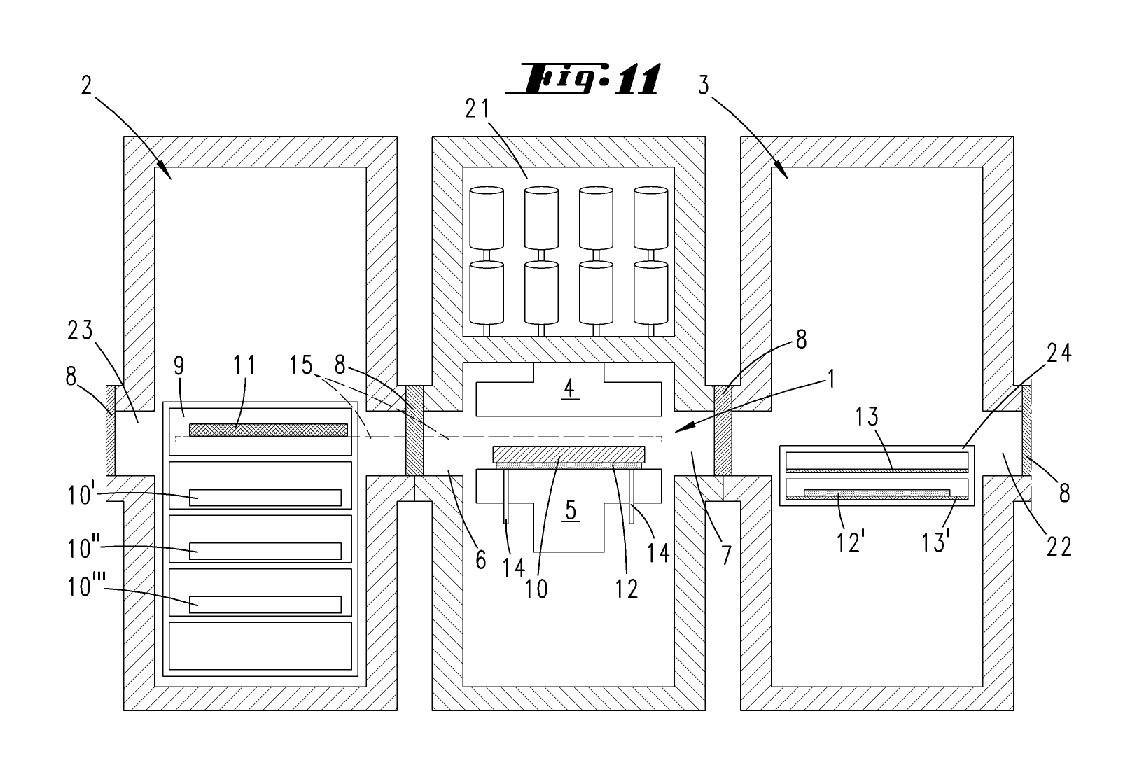

FIG. 11 shows an illustration subsequent to FIG. 10, in which the shielding plate 11 has been moved from the process chamber 1 into the magazine 9 so that the coating process may take place;

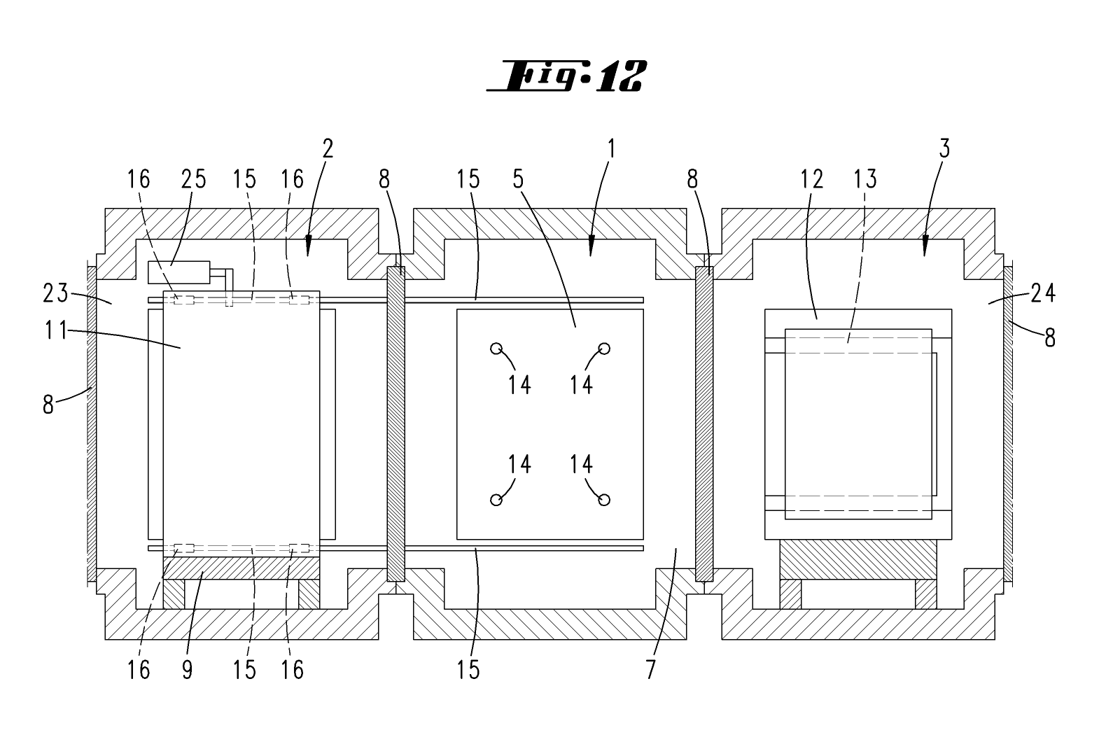

FIG. 12 shows a schematic sectional illustration according to the line XII-XII in FIG. 1;

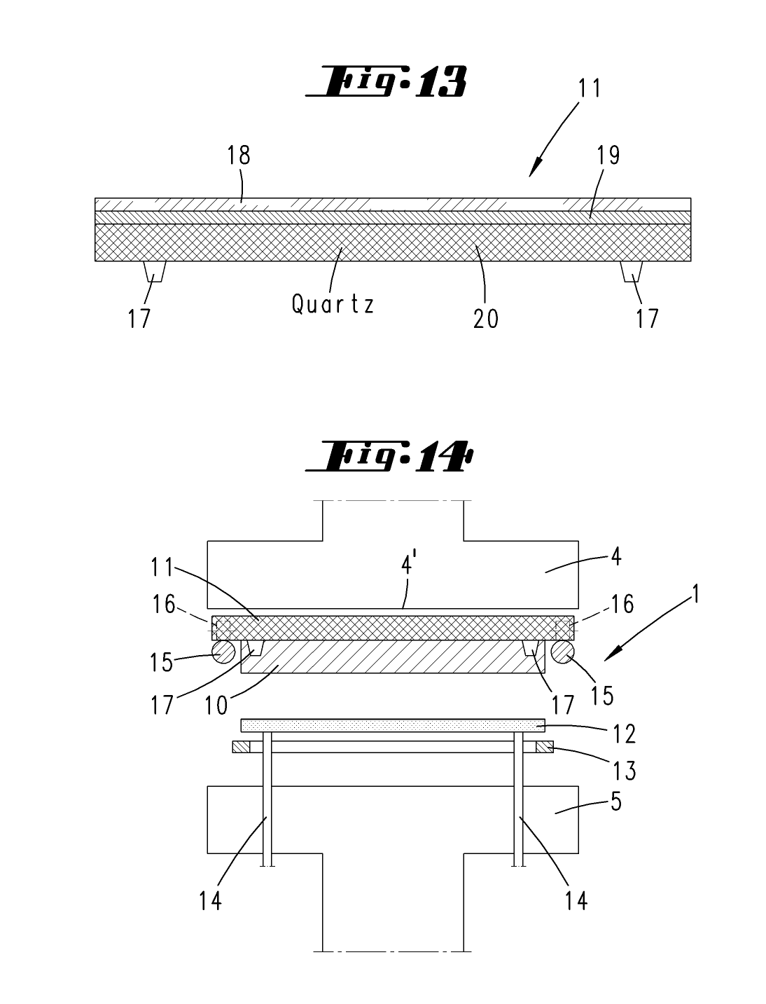

FIG. 13 shows the cross-sectional profile of the shielding plate 11; and

FIG. 14 schematically shows a cross-section of the process chamber for illustrating the conveying devices for the shielding plate 11 and the substrate 12.

The device illustrated in the drawings is composed of a process chamber 1 which is closed gas-tight with respect to the surroundings, a gas supply unit 21 situated above the process chamber 1, and a gas inlet element 4, situated in the process chamber 1 and supplied with process gases which may be transported via carrier gases into the process chamber. The process chamber 1 may be evacuated by means of a vacuum pump, not illustrated.

FIG. 1 shows, to the right of the process chamber 1, a substrate storage chamber 3, which is connected to the process chamber 1 via a loading opening 7 which is closable by a gate 8. A magazine 24 which may be horizontally displaced in the direction of the double arrow P₃ is located inside the substrate storage chamber 8. The magazine 24 illustrated in the drawings has two levels, a substrate holder 13, 13′ which may also function as a substrate conveying device being respectively situated in each of the two levels. A large-area substrate 12, 12′ is situated on each of the substrate holders 13, 13′, respectively. In an exemplary embodiment which is not illustrated, the magazine 24 has a greater number of levels and is thus able to store a greater number of substrates 12, 12′. The magazine pockets in the magazine 24 may be loaded and unloaded through the loading opening 22, which likewise is closed by a gate 8. The substrate storage chamber 3 may likewise be evacuated by a vacuum device. In addition, a gas feed line (not illustrated) opens into the storage chamber 3 in order to flood the storage chamber 3 with an inert gas at atmospheric pressure so that the loading process may be carried out through the loading opening 22.

A mask storage chamber 2 is illustrated to the left of the process chamber 1 in FIG. 1. The same as for the substrate storage chamber 3, the mask storage chamber 2 has a gas-tight housing and may be evacuated using a vacuum device, not illustrated. Here as well, a gas supply is provided in order to flood the mask storage chamber 2 with an inert gas. A magazine 9 which has a multiplicity of magazine pockets and which is displaceable in the direction of the double arrow P₂ in the manner of an elevator is situated in the mask storage chamber 2. These magazine pockets, which are arranged one above the other in the manner of the floors of a building, are loadable with masks 10, 10′, 10″, 10″′. The masks 10, 10′, 10″, 10″′ are secured to mountings (not illustrated) so that, as described in greater detail below, they may be transported by a shielding plate 11, situated in the lowest pocket, into the process chamber 1 through the loading opening 6, via which the mask storage chamber 2 is connected to the process chamber 1 and which is situated opposite from the loading opening 7. Situated on the side opposite from the loading opening 6, which is closable by a gas-tight gate 8, is a loading opening 23 which likewise is closable in a gas-tight manner by a gate 8. This loading opening 23 is connected to a further mask storage chamber 2, not illustrated, which likewise stores additional masks in a vertically displaceable magazine 9. Masks may be exchanged between the two mask storage chambers 2 via the loading opening 23.

FIG. 11 schematically shows a horizontal section of the device in the region of the process chamber. The magazine 24, which is composed of a rack having a multiplicity of levels, is located in the substrate storage chamber 3 illustrated on the right hand side. Each level carries a fork-shaped substrate holder 13, by means of which the substrate 12 resting thereon may be brought to the left, through the open loading opening 7, and into the process chamber 1. A susceptor 5 having a rectangular shape in plan view and which is vertically displaceable in the direction of the double arrow P₁ shown in FIG. 1 is located in the process chamber, beneath the gas inlet element 4. Support pins 14 which protrude beyond the surface of the susceptor 5 in the lowered position of the susceptor and on which the substrate 12 may be placed, are located in vertical openings in the susceptor 5. The substrate 12 may be placed on the top side of the susceptor 5 facing the gas inlet element 4 by raising the susceptor 5 to the position illustrated in FIG. 10 or FIG. 11.

FIG. 12 also illustrates the rails 15, which are shown only in dashed lines in FIG. 1, on which the shielding plate 11 may be moved with the aid of rollers 16 associated with the shielding plate 11. A total of two rail pairs 15 are provided. One rail pair 15 is located in the process chamber 1, approximately beneath the level of the gas inlet element 4. Another rail pair is situated within the magazine 9 or within the mask storage chamber 2 in such a way that, at least in a loading position, it is in flush alignment with the rail pair 15 situated in the process chamber 1. The shielding plate 11 may be displaced in the horizontal direction on the rails 15. For this purpose, a drive device 25 is provided which engages on the shielding plate 11, for example, by means of pneumatic cylinders or hydraulic cylinders, or with a spindle drive.

FIG. 14 schematically shows the cross-section of the process chamber. The ceiling of the process chamber 1 is formed by the underside 4′ of a gas inlet element 4. The underside 4′ has a multiplicity of gas discharge openings, not illustrated, which are uniformly distributed on the surface. During the coating process, the process gas is able to flow into the process chamber 1 via the gas discharge surface 4′, which in the exemplary embodiment has a rectangular shape in plan view. An inert gas is able to flow through the gas discharge surface 4′ and into the process chamber 1 during the mask exchange or the substrate exchange, or in an idle state.

By use of the drive device 25 illustrated in FIG. 12, the shielding plate 11 may be brought from the storage position illustrated in FIG. 12 into the working position illustrated in FIG. 14, in which the shielding plate 11 is situated beneath the gas discharge surface 4′ of the gas inlet element 4.

The gas inlet element is heated to temperatures between 200° and 400° using a heater, not illustrated. In other processes, however, the gas inlet element 4 may be heated to higher process temperatures. In the exemplary embodiment, the shielding plate 11 has a three-layer design. The plate 18 facing the gas inlet element 4 is a glass plate 1 mm thick. A foil 100 μm thick made of a highly reflective material, in particular a metal, especially Invar, gold, or aluminum, is situated between this glass plate 18 and a lower quartz glass plate 20, which may have a thickness between 8 mm and 10 mm. The foil 19 is floatingly-mounted between the glass plate and the quartz glass plate 20 due to the different thermal expansion properties. The emissivity of the foil in the range of the thermal radiation is less than 0.1.

By means of the shielding plate 11, the thermal radiation emitted by the gas inlet element 4 is shielded in the direction of the susceptor 5 or the substrate 12 situated on the susceptor.

The susceptor 5 has a cooling device by means of which the surface temperature of the susceptor 5 may be cooled to temperatures between −80° C. and 20° C. The substrate 12 is held at a cooled temperature as a result of the substrate resting on a cooled surface of the susceptor 5.

As discussed above, the shielding plate 11 forms the transport element by means of which a mask 10, 10′, 10″, 10″′ may be brought from the magazine 9 of the mask storage chamber 2 into the process chamber 1. For this purpose, the masks 10 or mask frames, not illustrated in the drawings, have counter-mountings which are able to cooperate with clamping elements 17 of the shielding plate 11, which are only schematically illustrated in FIGS. 13 and 14. The clamping elements 17 are adapted so that they may be used to grip and release a mask 10.

The mode of operation of the device is as follows:

FIG. 1 shows the device in an idle position in which the susceptor 5 assumes a lowered position, the gates 8 of the loading openings 6, 7, 22, and 23 are closed, and no substrate 12 or mask 10 is present in the process chamber 1, and neither is the shielding plate 11. The total pressure inside the process chamber may be between 0.1 mbar and 2 mbar. The process chamber 1 may be flushed with an inert gas. The substrate storage chamber 3 and the mask storage chamber 2 are at the same total pressure.

FIG. 2 shows the first step for loading the process chamber 1. Using the drive device 25, the shielding plate 11 is moved from the lowest level of the magazine 9, which is in front of the loading opening 6, over the rails 15, through the open loading opening 6, and into the process chamber 1.

At the same time, the magazine 9 is lowered in the direction of the arrow P₂ illustrated in FIG. 3. The magazine 24 is likewise lowered in the direction of the arrow P₃ into the position illustrated in FIG. 3. The shielding plate 11 is in the operating position, illustrated in FIG. 3, beneath the gas inlet element 4.

In a subsequent step the shielding plate 11, driven by the drive device 25, moves on the rails 15, through the loading opening 6, and back into the mask storage chamber 2, where it moves into a pocket in which a mask 10 is present.

The shielding plate 11 then reaches its position illustrated in FIG. 5, in which the mask 10 is secured on the underside of the shielding plate 11 by means of the clamping elements 17.

FIG. 6 shows how the shielding plate 11 transports the mask 10, secured on its underside, through the loading opening 6 into the process chamber 1 until it reaches the position illustrated in FIG. 7, in which the shielding plate 11 and the mask 10 which it carries are situated beneath the gas inlet element 4. The heat given off by the gas inlet element 4 is now shielded with respect to the susceptor 5.

FIG. 8 shows the subsequent step in which, after the loading opening 7 is opened, a substrate 12 is introduced into the process chamber 1 by means of the conveying device 13. The substrate 12 is set down on the support pins 14 so that it has a clearance with respect to the top side of the susceptor 5. The conveying device 13, which in the exemplary embodiment is a substrate holder, is then moved back into the magazine 24, and the loading opening 7 is closed by closing the gate 8.

The susceptor 5 is then moved upwardly in the direction of the arrow P₁ in FIG. 10 until the substrate 12 rests on it.

Lastly, the shielding plate 11 is moved from the process chamber 1 into the storage chamber 2, so that the process position illustrated in FIG. 11 is reached. In this process position, process gases which are mixed or generated in the gas supply unit 21 are introduced through the gas inlet element 4 into the process chamber 1 at a total pressure between 0.1 mbar and 2 mbar. The process gases can react chemically inside the process chamber 1, for example on the substrate surface of the substrate 12, in order to deposit a layer on that surface. The mask 10 is a shadow mask, so that the growth occurs only at the locations which are not shaded.

The gas supply unit 21 is able in particular to supply the gas inlet element 4 with a monomer, which is transported by a carrier gas. This monomer has the property of condensing at low temperatures. When the monomer meets the cooled substrate surface of the substrate 12, it condenses there and polymerizes to form a polymer.

Without cooling of the gas inlet element, after the coating process is completed, the shielding plate 11 is brought from the process position illustrated in FIG. 11 into the position illustrated in FIG. 10. The susceptor 5 is lowered into the position illustrated in FIG. 9. The mask 8 is lifted from the substrate surface of the substrate 12 by means of the shielding plate 11, or the substrate 12 is removed from the mask 10 by lowering the support pins 14. The substrate 12 is then conveyed from the process chamber back into the magazine 24 with the aid of a substrate holder 13.

Another substrate 12′ may then be brought into the process chamber 1 with the aid of a substrate holder 13′ in order to be coated in the previously described manner.

The device is also suited for depositing OLEDs or semiconductor layers, for example using the MOCVD process.

All features disclosed are (in themselves) pertinent to the invention. The disclosure content of the associated/accompanying priority documents (copy of the prior application) is also hereby included in full in the disclosure of the application, including for the purpose of incorporating features of these documents in claims of the present application. The subsidiary claims in their optional subordinated formulation characterize independent inventive refinement of the prior art, in particular to undertake divisional applications based on these claims.

List of reference numerals:

| | | | |
|---|---|---|---|
| 1 | Process chamber | P | Arrow |
| 2 | Mask storage chamber | P₁ | Arrow |
| 3 | Substrate storage chamber | P₂ | Arrow |
| 4 | Gas inlet element | P₃ | Arrow |
| 5 | Susceptor | | |
| 6 | Loading opening | | |
| 7 | Loading opening | | |
| 8 | Gate | | |
| 9 | Magazine | | |
| 10 | Mask | | |
| 11 | Shielding plate | | |
| 12 | Substrate | | |
| 13 | Substrate holder, substrate conveying device | | |
| 14 | Support pin | | |
| 15 | Rail | | |
| 16 | Roller guide | | |
| 17 | Clamping element | | |
| 18 | Quartz glass plate | | |
| 19 | Reflective foil | | |
| 20 | Quartz glass plate | | |
| 21 | Gas supply unit | | |
| 22 | Loading opening | | |
| 23 | Loading opening | | |
| 24 | Magazine | | |
| 25 | Drive device | | |

1. A device for treating a substrate (12), having a process chamber (1), at least one storage chamber (2, 3) for storing substrates (12) to be treated in the process chamber (1), which is connected to the process chamber (1) via a loading opening (6, 7), or for storing masks (10, 10′, 10″, 10″′) to be used in the treating process, having a conveying device (13) for loading and unloading substrates or masks (10, 10′, 10″, 10″′) into and from the process chamber (1) through the loading opening (6, 7), having a temperature-controllable gas inlet element (4) for introducing a starting material together with a carrier gas into the process chamber (1), a susceptor (5) situated opposite from the gas inlet element (4) for receiving a substrate (12) to be treated, having a shielding plate (11) which, in a shielding position, is situated between the gas inlet element (4) and the susceptor (5) or a mask (10) in order to shield the substrate (12) or the mask (10) from the influence of heat from the gas inlet element (4), having a shielding plate displacement device (15, 16) in order to displace the shielding plate (11), before the substrate (12) is treated, from the shielding position in front of the gas inlet element (4) into a storage position and, after the substrate (12) is treated, to displace the shielding plate (11) from the storage position back into the shielding position, characterized in that, in the storage position, the shielding plate (11) is situated inside one of the storage chambers (2, 3).

2. A device according to claim 1, further characterized by a first storage chamber (3) for storing at least one substrate (12), and a second storage chamber (2) in which the shielding plate (11) is accommodated during the treatment process.

3. A device according to claim 2, further characterized in that the second storage chamber (2) is a mask storage chamber for storing at least one mask (10, 10′, 10″, 10″′), which may be brought from the mask storage chamber into the process chamber (1) with the aid of the shielding plate displacement device (15, 16) or with the aid of the shielding plate (11).

4. A device according to claim 1, further characterized in that the surface of the shielding plate (11) facing the gas inlet element (4) and/or facing the susceptor or the mask (10) is highly reflective.

5. A device according to claim 1, further characterized in that the shielding plate (11) has a highly reflective foil (19) situated between two glass or quartz plates (18, 20).

6. A device according to claim 3, further characterized in that the mask storage chamber has a magazine (9), which is displaceable in a vertical direction, for accommodating the shielding plate (11) and at least one mask (10).

7. A device according to claim 3, further characterized in that the shielding plate displacement device (15, 16) has a drive device (25) situated in the mask storage chamber, and a rail arrangement which extends into the process chamber (1).

8. A device according to claim 3, further characterized in that a loading opening (6) in the process chamber (1) which connects the process chamber (1) to the mask storage chamber is situated opposite from the loading opening (7) which connects the process chamber (1) to a substrate storage chamber.

9. A device according to claim 1, further characterized by support pins (14) which protrude from the susceptor (5) in the direction of the gas inlet element (4) for set-down of the substrate (12) using a substrate conveying device (13) which is fork-shaped, the susceptor (5) being vertically displaceable in order to bring it into heat-conductive contact with the substrate (12) by means of an upward movement.

10. A method for treating a substrate (12), comprising:
in a process chamber (1), bringing a shielding plate (11), with the aid of a shielding plate displacement device (15, 16), into a shielding position between a temperature-controlled gas inlet element, for introducing a starting material together with a carrier gas, and a susceptor (5), for receiving the substrate (12);
bringing the substrate (12) into the process chamber (1) with the aid of a conveying device (13) and setting the substrate down on the susceptor (5);
bringing the shielding plate (11) from the shielding position into a storage position;
treating the substrate (12) by depositing a layer on the substrate (12) by introducing the starting material via the temperature-controlled gas inlet element (4);
bringing the shielding plate (11) from the storage position back into the shielding position using the shielding plate displacement device (15, 16);
bringing the substrate (12) from the process chamber (1) into a storage chamber (3) with the aid of the conveying device (13),
wherein, when in the storage position, the shielding plate (11) is in the a storage chamber (2, 3).

11. A method according to claim 10, wherein the mask in the storage position is in a mask storage chamber, and is brought into the shielding position through the loading opening (6).

12. A method according to claim 10, wherein a mask (10) is brought from a mask storage chamber into the process chamber (1) using the shielding plate displacement device (15, 16) or with the aid of the shielding plate (11).
